(19) United States
(12) Patent Application Publication
(10) Pub. No.: US 2011/0031848 A1
(43) Pub. Date: Feb. 10, 2011

(54) MULTILAYERED PIEZOELECTRIC ELEMENT AND ULTRASONIC MOTOR

(75) Inventor: Nagahide SAKAI, Higashimurayama-shi (JP)

Correspondence Address: SCULLY SCOTT MURPHY & PRESSER, PC, 400 GARDEN CITY PLAZA, SUITE 300, GARDEN CITY, NY, 11530, US

(73) Assignee: OLYMPUS CORPORATION, Tokyo (JP)

(21) Appl. No.: 12/907,327

(22) Filed: Oct. 19, 2010

Related U.S. Application Data
(63) Continuation of application No. PCT/JP2009/057141, filed on Apr. 7, 2009.

(30) Foreign Application Priority Data
Apr. 22, 2008 (JP) 2008-111711

(51) Int. Cl. H01L 41/047

(52) U.S. Cl. 310/366

(57) ABSTRACT

A multilayered piezoelectric element is manufactured as follows. First and second internal electrode regions including power supply extracting portions are separately formed in a plurality of piezoelectric members. A shrink matching region is separately formed between the extracting portions of the first and second internal electrode regions. The multilayered piezoelectric element is manufactured by stacking and sintering the plurality of piezoelectric members into a rectangular shape.

### CROSS-REFERENCE TO RELATED APPLICATIONS

This is a Continuation Application of PCT Application No. PCT/JP2009/057141, filed Apr. 7, 2009, which was published under PCT Article 21(2) in Japanese.

This application is based upon and claims the benefit of priority from prior Japanese Patent Application No. 2008-111711, filed Apr. 22, 2008, the entire contents of which are incorporated herein by reference.

### BACKGROUND OF THE INVENTION

1. Field of the Invention

The present invention relates to a multilayered piezoelectric element suitable for an ultrasonic motor used as an actuator of, e.g., a camera shake correction unit or AF lens of a digital camera.

2. Description of the Related Art

An ultrasonic motor of this kind is generally configured to generate an elliptical vibration by generating a longitudinal vibration and flexural vibration by applying a voltage to a multilayered piezoelectric element, and transmit this elliptical vibration to a driven member via a driving member, thereby frictionally driving the driven member.

A multilayered piezoelectric element as described above is manufactured by stacking and sintering a plurality of piezoelectric members in which a plurality of internal electrode regions forming piezoelectric active regions are formed. For the multilayered piezoelectric element, therefore, various measures have been proposed to suppress, e.g., an element fracture, a crack, strain, and interlayer shoot caused by the internal stress generated during sintering by the shrink difference between the internal electrode region and a region other than the internal electrode region.

For example, the width of the proximal end, on the electrode side, of an electrode extracting portion of an electrode formation portion in each layer is made smaller than that on the distal end (outer surface) side of the electrode extracting portion. This arrangement suppresses the internal stress caused by the shrink difference during sintering. A technique like this is disclosed in, e.g., Jpn. Pat. Appln. KOKAI Publication No. 2007-109754.

It is, however, difficult for the arrangement disclosed in above-mentioned Jpn. Pat. Appln. KOKAI Publication No. 2007-109754 to eliminate the shrink difference in a region close to the outer surface of the electrode extracting portion. This decreases the flatness of the extracting surface of the internal electrode region. Consequently, when connecting a power supply member such as a flexible printed circuit board to an external electrode surface by thermocompression bonding by using a conductive adhesive or the like, an electrical connection defect occurs, or it becomes difficult to accurately assemble peripheral members.

### BRIEF SUMMARY OF THE INVENTION

The present invention has been made in consideration of the above situation, and has as its object to provide a multilayered piezoelectric element and ultrasonic motor that implement a high-quality sintering process with a simple arrangement, thereby implementing stable high-quality assembly.

In order to achieve the above object, according to a first aspect of the invention, there is provided a multilayered piezoelectric element in which piezoelectric members are stacked and sintered, and has piezoelectric active regions, the multilayered piezoelectric element comprising:

a plurality of internal electrode regions including power supply extracting portions which are formed on the plurality of piezoelectric members respectively;

a shrink matching region formed between the extracting portions of the plurality of internal electrode regions formed in the piezoelectric member.

In order to achieve the above object, according to a first aspect of the invention, there is provided an ultrasonic motor which drives a driven member, the ultrasonic motor comprising:

a multilayered piezoelectric element in which vibrations in two perpendicular directions are generated as a driving force to drive the driven member,

wherein in the multilayered piezoelectric element, a plurality of piezoelectric members comprising a plurality of internal electrode regions including power supply extracting portions and a shrink matching region formed between the extracting portions of the plurality of internal electrode regions are stacked and sintered, and a plurality of piezoelectric active regions are formed in the internal electrode regions.

### BRIEF DESCRIPTION OF THE SEVERAL VIEWS OF THE DRAWING

The accompanying drawings, which are incorporated in and constitute a part of the specification, illustrate embodiments of the invention, and together with the general description given above and the detailed description of the embodiments given below, serve to explain the principles of the invention.

FIG. 1 is an exploded perspective view for explaining the arrangement of a multilayered piezoelectric element according to an embodiment of the present invention;

FIG. 2 is a plan view two-dimensionally showing the positional relationship between a plurality of piezoelectric members shown in FIG. 1;

FIG. 3 is an exemplary exploded perspective view showing the sintered state of the plurality of piezoelectric members shown in FIG. 1;

FIG. 4 is a plan view showing the sintered state of the plurality of piezoelectric members shown in FIG. 1, when viewed from the outer surface;

FIG. 5 is a plan view showing the way a flexible printed circuit board is connected to external electrodes shown in FIG. 1 by thermocompression bonding by using a thermocompression bonding machine;

FIG. 6 is a perspective view for explaining the arrangement of the main parts of an ultrasonic motor according to the embodiment of the present invention; and

FIG. 7 is a plan view for explaining the arrangement of a multilayered piezoelectric element according to another embodiment of the present invention.

### DETAILED DESCRIPTION OF THE INVENTION

A multilayered piezoelectric element and ultrasonic motor according to an embodiment of the present invention will be explained in detail below with reference to the accompanying drawings.

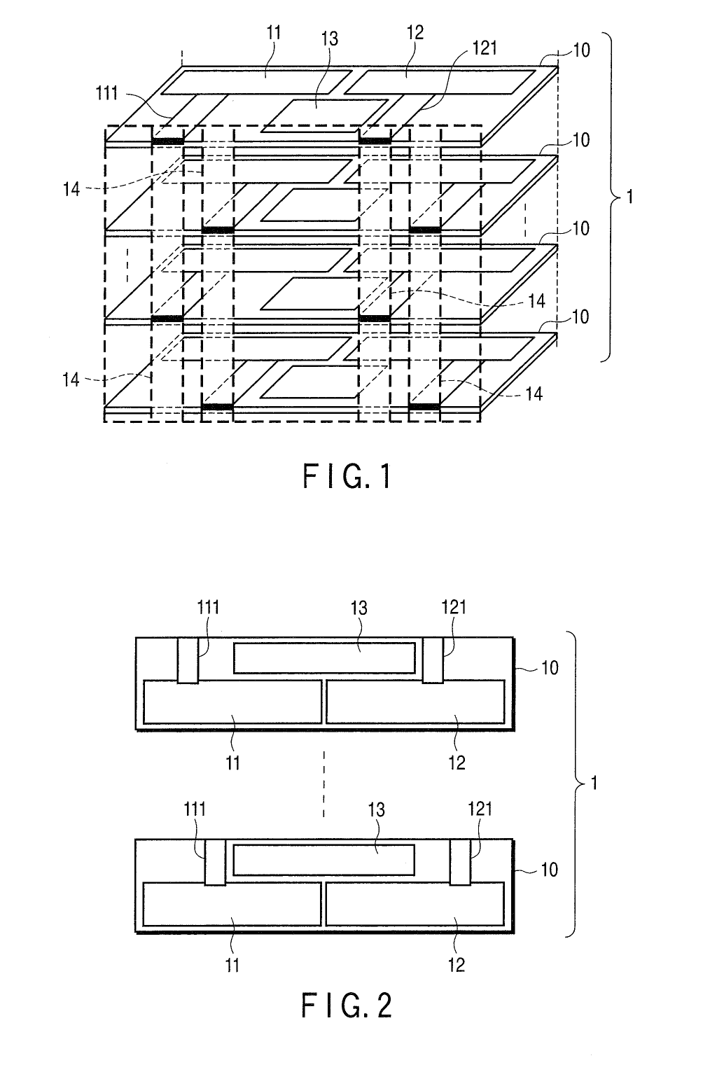

FIG. 1 is a view showing a multilayered piezoelectric element 1 according to the embodiment of the present invention. A plurality of piezoelectric members 10 are similarly formed to have a thickness of about 10 to 200 μm by using, e.g., lead zirconate titanate, and stacked into a rectangular shape.

On one surface of each of the plurality of piezoelectric members 10, a plurality of, e.g., two, first and second internal electrode regions 11 and 12 are formed to have a thickness of about 2 to 2.5 μm at a predetermined interval (see FIG. 2). The two, first and second internal electrode regions 11 and 12 are formed by a method such as screen printing by using a refractory conductive material such as silver palladium capable of withstanding the sintering temperature of lead zirconate titanate or the like. Power supply extracting portions 111 and 121 are respectively extended from the first and second internal electrode regions 11 and 12 to the end portion of the piezoelectric member 10 as an element outer surface.

When the piezoelectric members 10 are stacked, the first and second internal electrode regions 11 and 12 are respectively stacked in the same positions. In addition, the extracting portions 111 and 121 of the first and second internal electrode regions 11 and 12 are formed in so-called staggered positions with respect to the extracting portions 111 and 121 of the other first and second internal electrode regions 11 and 12.

Also, in the above-mentioned piezoelectric member 10, a shrink matching region 13 is formed in a region sandwiched between the extracting portions 111 and 121 of the first and second internal electrode regions 11 and 12. The shrink matching region 13 is made of, e.g., the same material as that of the first and second internal electrode regions 11 and 12. The shrink matching region 13 is preferably formed, e.g., in a position 0.2 mm or more inside the end portion of the piezoelectric member 10, at a distance of 0.15 mm or more from the first and second internal electrode regions 11 and 12, and within the range of 0.2 mm×0.2 mm or more.

Since the first and second internal electrode regions 11 and 12 and shrink matching region 13 are formed as described above, even if smearing occurs when forming these regions by a method such as screen printing, it is possible to reliably prevent short circuits between them, and facilitate the manufacture.

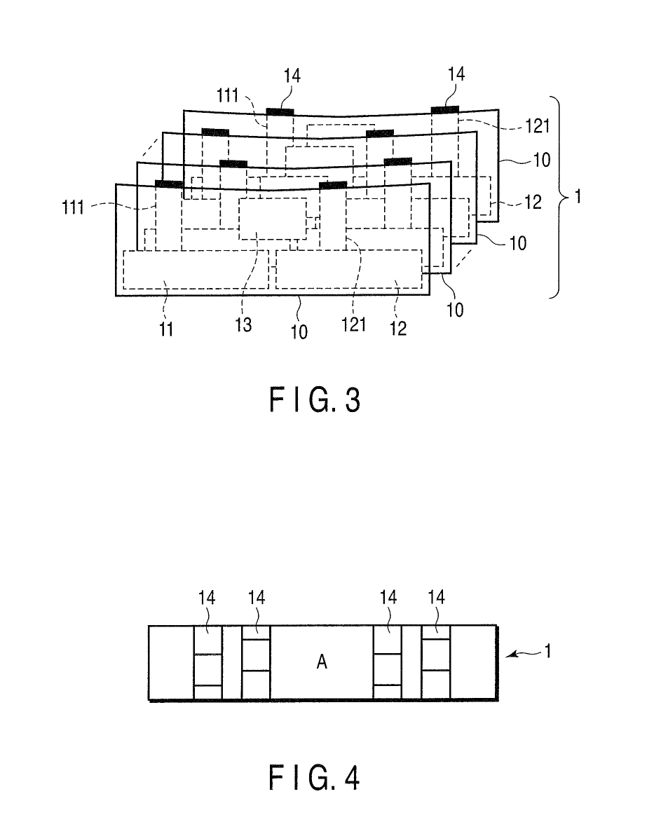

In the above arrangement, the plurality of piezoelectric members 10 are stacked as shown in FIG. 1 and integrally sintered into a rectangular shape at a sintering temperature of about 800° C. to 1,500° C. During this process, the shrink matching region 13 shrinks similarly to the first and third internal electrode regions 11 and 12. Consequently, as shown in FIG. 3, the plurality of piezoelectric members 10 are sintered with high accuracy with high flatness on the outer surface side on which external electrodes 14 are to be formed.

In the plurality of piezoelectric members 10 thus sintered, the extracting portions 111 and 121 connected to the first and second internal electrode regions 11 and 12 are exposed to one outer surface of the rectangular shape of the piezoelectric members 10. The external electrodes 14 short-circuit corresponding ones of the extracting portions 111 and 121 exposed to the outer surface.

The external electrodes 14 are formed to have a thickness of 10 μm or more by screen printing using a conductive material such as silver palladium or silver. After being thus formed, the external electrodes 14 undergo a polarizing process. The first and second internal electrode regions 11 and 12 of the plurality of stacked piezoelectric members 10 function as two independent piezoelectric active regions 15 and 16. Since the flatness on the outer surface side of the integrally sintered multilayered piezoelectric element 1 is set at the desired high value as described above, the external electrodes 14 can be formed with high accuracy on the outer surface of the multilayered piezoelectric element 1.

When an alternating signal having a desired phase difference is applied between the above-mentioned external electrodes 14, the two piezoelectric active regions 15 and 16 formed by the first and second internal electrode regions 11 and 12 stacked in the stacking direction generate vibrations in two perpendicular directions other than the stacking direction, e.g., a longitudinal vibration and flexural vibration, thereby generating an elliptical vibration in the multilayered piezoelectric element 1 obtained as a stack.

As described above, the first and second internal electrode regions 11 and 12 including the power supply extracting portions 111 and 121 are separately formed in the plurality of piezoelectric members 10, and the shrink matching regions 13 are separately formed between the extracting portions 111 and 121 of the first and second internal electrode regions 11 and 12. The above-mentioned multilayered piezoelectric element 1 is manufactured by stacking and sintering the plurality of piezoelectric members 10 into a rectangular shape.

When stacking and sintering the plurality of piezoelectric members 10, each shrink matching region 13 shrinks similarly to the first and second internal electrode regions 11 and 12, so the outer surface side on which the external electrodes 14 are to be formed is sintered with high accuracy with high flatness in, e.g., a central portion A shown in FIG. 4.

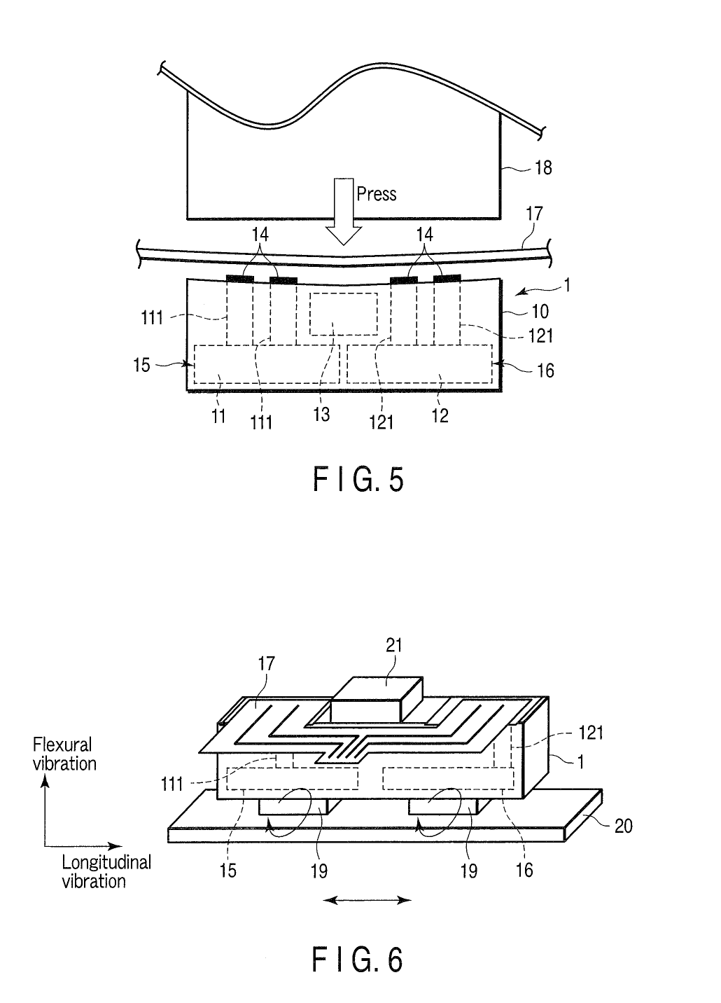

Consequently, the external electrodes 14 can be formed with high accuracy on the outer surface side. As shown in FIG. 5, therefore, it is possible, by using a thermocompression bonding machine 18, to accurately and reliably perform an adhering operation of connecting a flexible printed circuit board 17 as a power supply member to the external electrodes 14 by thermocompression bonding using a conductive adhesive. In addition, high-accuracy assembly to peripheral members is possible.

An ultrasonic motor including the aforementioned multilayered piezoelectric element 1 according to the embodiment of the present invention will be explained below with reference to FIG. 6.

On the lower surface side of the plurality of piezoelectric members 10, i.e., on the lower surface side corresponding to the two piezoelectric active regions 15 and 16 formed by the first and second internal electrode regions 11 and 12, friction members 19 as driving force extracting members are fixed to, e.g., the antinode positions of a flexural vibration with an adhesive. The friction members 19 are in contact with a driven member 20. The multilayered piezoelectric element 1 and the driven member 20 are accommodated in a housing (not shown) by using rolling members such as balls so as to be drivable in the directions of arrows shown in FIG. 6.

On the upper surface of the multilayered piezoelectric element 1, a positioning pressing mechanism 21 is placed to correspond to, e.g., the node of a longitudinal vibration. With the multilayered piezoelectric element 1 being positioned, the positioning pressing mechanism 21 presses the multilayered piezoelectric element 1 to bring the friction members 19 in tight contact with the driven member 20 so that it is drivable.

Also, the flexible printed circuit board 17 is connected to the external electrodes 14 of the multilayered piezoelectric element 1 by thermocompression bonding by using a conductive adhesive or the like. An alternating signal having a phase difference is applied to the extracting portions 111 and 121 of the plurality of internal electrode regions 11 and 12 via the flexible printed circuit board 17. In the multilayered piezoelectric element 1, therefore, the two piezoelectric active regions 15 and 16 formed by the first and second internal electrode regions 11 and 12 stacked in the stacking direction generate a longitudinal vibration perpendicular to the stacking direction and a flexural vibration, thereby generating an elliptical vibration. By using this elliptical vibration as a driving force, the friction members 19 frictionally drives the driven member 20 in the arrow directions.

In the plurality of piezoelectric members 10 as described above, the first and second internal electrode regions 11 and 12 including the power supply extracting portions 111 and 121 are formed, and the shrink matching region 13 is formed between the extracting portions 111 and 121 of the first and second internal electrode regions 11 and 12. The multilayered piezoelectric element 1 is manufactured by stacking and sintering the plurality of piezoelectric members 10 having this arrangement. When a predetermined alternating signal is applied to the two piezoelectric active regions 15 and 16 formed by the stacked first and second internal electrode regions 11 and 12, a longitudinal vibration and flexural vibration are generated in the multilayered piezoelectric obstruction 1, and this generates an elliptical vibration.

When the plurality of piezoelectric members 10 are stacked and sintered, each shrink matching region 13 shrinks similarly to the first and second internal electrode regions 11 and 12. Accordingly, the outer surface side on which the external electrodes 14 are to be formed is sintered with high accuracy and with high flatness.

This makes it possible to accurately form the external electrodes 14 on the outer surface side of the multilayered piezoelectric element 1. That is, it is possible to accurately and reliably perform the adhering operation of connecting the flexible printed circuit board 17 to the external electrodes 14 by thermocompression bonding using a conductive adhesive. In addition, since high-accuracy assembly to peripheral members is possible, a simple and easy motor assembling work can be implemented. That is, it is readily possible to increase the motor productivity.

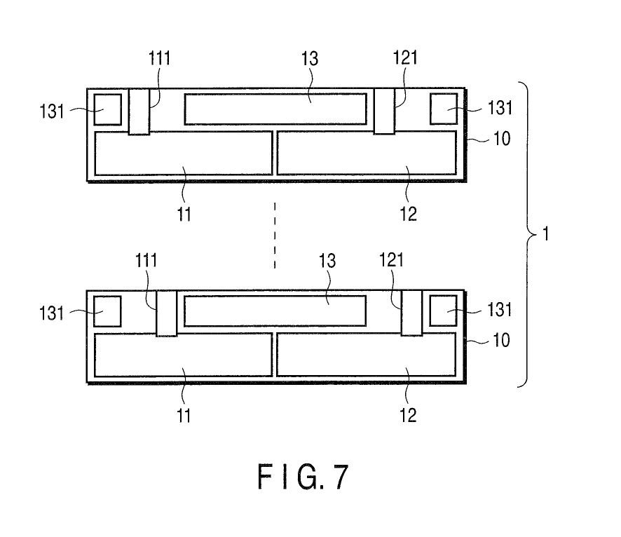

Note that the present invention is not limited to the above embodiment, and the above-mentioned piezoelectric member 10 can also be configured as shown in, e.g., FIG. 7. In this embodiment shown in FIG. 7, the same reference numerals as in the embodiment shown in FIGS. 1 and 2 denote the same parts, and a detailed explanation thereof will be omitted.

In the embodiment shown in FIG. 7, as in the embodiment described above, a shrink matching region 13 is formed between power supply extracting portions 111 and 121 extended from first and second internal electrode regions 11 and 12 of a piezoelectric member 10, and second shrink matching regions 131 are formed between the side portions of the piezoelectric member 10 and the extracting portions 111 and 121 of the first and second internal electrode regions 11 and 12.

In this embodiment, when the plurality of piezoelectric members 10 are stacked and sintered, both the shrink matching regions 13 and second shrink matching regions 131 shrink similarly to the first and second internal electrode regions 11 and 12. This forms a stack in which even the corners on the outer surface side of the plurality of piezoelectric members 10 have a desired flatness. Accordingly, it is possible to implement a stack in which the overall flatness increases to the corners of the outer surface on which external electrodes 14 of a multilayered piezoelectric element 1 are to be formed. That is, better effects can be obtained.

The above embodiments have been explained by taking, as an example, the arrangement in which the two, first and second internal electrode regions 11 and 12 are formed in the piezoelectric member 10. However, the present invention is not limited to this form, and it is of course also possible to form two or more internal electrode regions.

In addition, the above embodiments have been explained by taking, as an example, the arrangement in which an elliptical vibration is generated by generating a longitudinal vibration and flexural vibration in the multilayered piezoelectric element. However, the present invention is not limited to this form. For example, the above embodiments are also applicable to an arrangement that obtains a driving force by generating a desired vibration by generating two perpendicular vibrations, e.g., a longitudinal vibration and torsional vibration in a multilayered piezoelectric element, and similar effects are obtainable.

In the arrangements of the above embodiments, when stacking and sintering the plurality of piezoelectric members, each shrink matching region shrinks similarly to the internal electrode regions, so the outer surface side on which the external electrodes are to be formed is sintered with high accuracy and with high flatness. This makes it possible to accurately form the external electrodes on the outer surface side of the multilayered piezoelectric element, and facilitate the operation of accurately and reliably adhering the power supply member to the external electrodes. In addition, the multilayered piezoelectric element and peripheral members can accurately be assembled.

In the arrangements of the above embodiments, when stacking and sintering the plurality of piezoelectric members, each shrink matching region shrinks similarly to the internal electrode regions, so the outer surface side on which the external electrodes are to be formed is sintered with high accuracy and with high flatness. This makes it possible to accurately form the external electrodes on the outer surface side of the multilayered piezoelectric element. That is, it is possible to readily perform the operation of accurately and reliably adhering the power supply member to the external electrodes. In addition, since high-accuracy assembly to peripheral members is possible, a simple and easy motor assembling work can be implemented.

Furthermore, the above embodiments have been explained by taking, as an example, the arrangement in which the external electrodes 14 of the multilayered piezoelectric element 1 are arranged on one outer surface of the rectangular shape formed by stacking the piezoelectric members 10. However, the present invention is not limited to this form. For example, the above embodiments can also be applied to an arrangement in which the external electrodes 14 are separately arranged on a plurality of outer surfaces of the multilayered piezoelectric element 1, and similar effects can be obtained.

The present invention is not limited to the above embodiments, and can variously be modified when practiced without departing from the spirit and scope of the invention. In addition, the above embodiments include inventions in various stages, so various inventions can be extracted by properly combining a plurality of disclosed constituent elements.

For example, even when some of all the constituent elements disclosed in the embodiments are omitted, an arrangement from which these constituent elements are omitted can be extracted as an invention, provided that the problems described in the section of the problems to be solved by the invention can be solved, and the effects described in the section of the effects of the invention can be obtained.

What is claimed is:

1. A multilayered piezoelectric element in which piezoelectric members are stacked and sintered, and has piezoelectric active regions, the multilayered piezoelectric element comprising:
a plurality of internal electrode regions including power supply extracting portions which are formed on the plurality of piezoelectric members respectively;
a shrink matching region formed between the extracting portions of the plurality of internal electrode regions formed in the piezoelectric member.

2. The multilayered piezoelectric element according to claim 1, further comprising:
a shrink matching region formed between the extracting portion and an edge of the piezoelectric member.

3. The multilayered piezoelectric element according to claim 1, wherein the shrink matching region is made of the same material as that of the internal electrode region.

4. The multilayered piezoelectric element according to claim 2, wherein the shrink matching region is made of the same material as that of the internal electrode region.

5. The multilayered piezoelectric element according to claim 1, wherein the shrink matching region is formed by printing.

6. The multilayered piezoelectric element according to claim 2, wherein the shrink matching region is formed by printing.

7. The multilayered piezoelectric element according to claim 3, wherein the shrink matching region is formed by printing.

8. An ultrasonic motor which drives a driven member, the ultrasonic motor comprising:
a multilayered piezoelectric element in which vibrations in two perpendicular directions are generated as a driving force to drive the driven member,
wherein in the multilayered piezoelectric element, a plurality of piezoelectric members comprising a plurality of internal electrode regions including power supply extracting portions and a shrink matching region formed between the extracting portions of the plurality of internal electrode regions are stacked and sintered, and a plurality of piezoelectric active regions are formed in the internal electrode regions.

9. The ultrasonic motor according to claim 8, wherein the multilayered piezoelectric element generates an elliptical vibration by simultaneously generating a longitudinal vibration and a flexural vibration.
